(19) United States
(12) Patent Application Publication
(10) Pub. No.: US 2004/0240675 A1
(43) Pub. Date: Dec. 2, 2004

(54) Autonomic manipulation of noise sources within computers

(75) Inventors: Mark Allan Casparian, Raleigh, NC (US); Cory Allen Chapman, Raleigh, NC (US); James Stephen Rutledge, Durham, NC (US); Kenneth Scott Seethaler, Raleigh, NC (US)

Correspondence Address: IBM CORPORATION, PO BOX 12195, DEPT 9CCA, BLDG 002, RESEARCH TRIANGLE PARK, NC, 27709, US

(73) Assignee: International Business Machines Corporation, Armonk, NY

(21) Appl. No.: 10/447,477

(22) Filed: May 29, 2003

(51) Int. Cl. H04R 29/00; H03G 3/00

(52) U.S. Cl. 381/56; 381/61

(57) ABSTRACT

Audible noise emitted by devices included in computer systems is pre-characterized by producing a noise profile from a representative device. The noise profile includes information which is related to the sound emissions of the representative device. The profile can include information relative to fundamental and harmonic components of the representative device. The noise profiles are stored in a storage device which are accessible to the computer system. The computer system is monitored for certain system status and events and when specific events are detected an appropriate noise profile is selected. In certain embodiments, representative fundamental frequency profile information is replaced with actual operational frequency information. The selected noise profile is then used to generate a noise shaping audio signal which: removes the harshness of an edgy sound, alters the pitch, removes pure tones, suppresses and/or otherwise masks the sounds emitted by the devices.

### BACKGROUND OF THE INVENTION

This invention pertains to computer systems and other information handling systems and, more particularly, to a computer system in which audible self noise is predicted and manipulated.

As the need for computational power increases, so does the need to cool the devices which yield the additional power. When a device is a digitally clocked semiconductor-integrated circuit, the heat dissipated by the device is related to the clock frequency and the number of circuits switched by the clock. Computational power is increased by either increasing the clock frequency or by increasing the number of circuits switched, both yielding proportional increases in dissipated heat. When either the clock frequency or the number of circuits switched by the clock are increased beyond a predetermined amount, a cooling fan will be required. The cooling fan, however, produces audible emissions which are undesirable because the emissions are generally distracting to the user.

In a modern personal computer system, it is not uncommon to see a fan used for the system processor, the Northbridge chip, the power supply, and the video subsystem. In addition, the chassis itself can have one or more cooling fans. Each fan of this multitude of fans tending to contribute an undesirable component to the total audible emissions produced by the system and thereby exacerbating the total noise emissions of the system.

In the same manner, hard disk drives and other direct access storage devices deliver higher levels of performance by increasing platter rotational rates and acceleration rates of the head subassemblies. Increased rotational rates for the platter are often associated with higher levels of audible noise; higher rates of head subassembly acceleration have similar effect on audible noise.

As a result of increased noise levels from personal computer systems, compliance authorities in certain countries have adopted increasingly restrictive standards for audible noise emissions. However, there are different standards for random noise vs. pure-tone noise. The standards for pure tone noise are more restrictive because users find pure tones annoying. Conversely, users often find random noise pleasing.

Increased audible noise levels produced in response to the ever increasing demand for computational power are aggravated by increasingly restrictive standards for audible noise emissions.

Accordingly, there is in need to manipulate the audible noise levels produced by modern personal computer systems in order to fall into compliance and/or make the personal computing experience in more pleasurable one for the end-user.

### SUMMARY OF THE INVENTION

In a first embodiment, the audible noise emitted by a device included with a computer system is profiled. A noise profile is created which contains information related to the audible noise. The noise profiles are stored in a storage accessible to the computer system. The computer system is monitored for certain system status and events and when selected status and events are detected an appropriate noise profile is selected from the storage. A noise shaping audio signal is then generated based upon the selected noise profile.

In another embodiment, the audible noise emitted by a device included with a computer system is pre-characterized by producing a noise profile for the device. The noise profile of this embodiment includes parameters/wave data or the like which are related to the harmonic components of the fundamental frequency of a representative device. The fundamental frequency of the representative device serves as a presumed fundamental frequency for a device in operation and as the fundamental frequency from which the harmonic components are derived. The noise profiles are stored in a storage device which is accessible to the computer system. The computer system is monitored for certain system status and events and when the monitored status and events are detected an appropriate noise profile is selected from the storage device. The storage device can be a disk storage device or a solid state memory such as RAM. The presumed fundamental frequency is replaced with an actual operational frequency by detecting, measuring, or otherwise estimating the actual fundamental frequency of a device. The obtained/actual fundamental frequency data is then used in conjunction with the harmonic component data contained in the selected profile to generate a noise shaping audio signal.

The inventive concepts taught herein are also embodied as an apparatus having a memory or storage which holds a noise profile for a device included in the apparatus. A system monitor is provided which monitors system events. A processor is provided and is effective to select the noise profile when selected monitored events occur. The processor is adapted to generate a noise shaping audio signal based upon the noise profile.

In another embodiment, the noise profile retained in the storage includes information related to the harmonic components of a presumed fundamental frequency of the device. The processor is further effective to obtain an actual fundamental frequency for the device. In generating the noise shaping signal, the apparatus of this embodiment takes into account the actual fundamental frequency of the device and the harmonic compositional information stored in the noise profile to generate the sound.

In addition, the invention is also embodied as a method of doing business in which a provider of a service installs a noise profile in one or more computer systems at a client's location. The noise profile contains information related to the audio noise produced by a device included in one or more of the client's computer systems. The service provider also installs a program in one or more of the client's computer systems which shape the noise emitted by each computer system. The noise shaping program having instructions which are effective when executing in the computer system to monitor system status and events in the computer system. The installed program is additionally effective to respond to selected status and events by choosing an appropriate noise profile from the installed profiles. The installed program responds to selection of the noise profile by generating a noise shaping audio signal based upon the noise profile.

The invention can also be embodied as a program product stored in a computer readable medium in which computer readable program code is stored. The computer readable program code includes noise profile code stored on the medium accessibly to a computer system. The noise profile code being designed to load a noise profile which contains information related to audio noise produced by a device in the computer system. In addition, noise shaping code is stored on the medium and is further designed to monitor system status and events in the computer system, to respond to selected monitored status and events by selecting the noise profile. Responsive to the selection of the noise profile, a noise shaping audio signal is generated as a function of the noise profile.

### BRIEF DESCRIPTION OF THE DRAWINGS

Some of the purposes of the invention having been stated, others will appear as the description proceeds, when taken in connection with the accompanying drawings, in which:

FIG. 1 is a block diagram depicting a data processing system configured in accordance with an embodiment of the present invention;

FIG. 2 illustrates a logic flow diagram presenting logic in accordance with an embodiment of the present invention wherein noise modification parameters are taken from a noise profile;

FIG. 3 illustrates a flow diagram presenting logic flow configured in accordance with an embodiment of the present invention noise modification parameters are taken from a noise profile and wherein the fundamental frequency of the device under consideration is taken from other than the profile;

FIG. 4 is a block diagram configured in accordance with a hardware embodiment of the present invention; and

FIG. 5 illustrates the steps taken by a service provider in deploying a service according to a business method embodiment of the present invention.

### DETAILED DESCRIPTION OF THE ILLUSTRATIVE EMBODIMENTS

While the present invention will be described more fully hereinafter with reference to the accompanying drawings, in which a preferred embodiment of the present invention is shown, it is to be understood at the outset of the description which follows that persons of skill in the appropriate arts may modify the invention here described while still achieving the favorable results of this invention. Accordingly, the description which follows is to be understood as being a broad, teaching disclosure directed to persons of skill in the appropriate arts, and not as limiting upon the present invention.

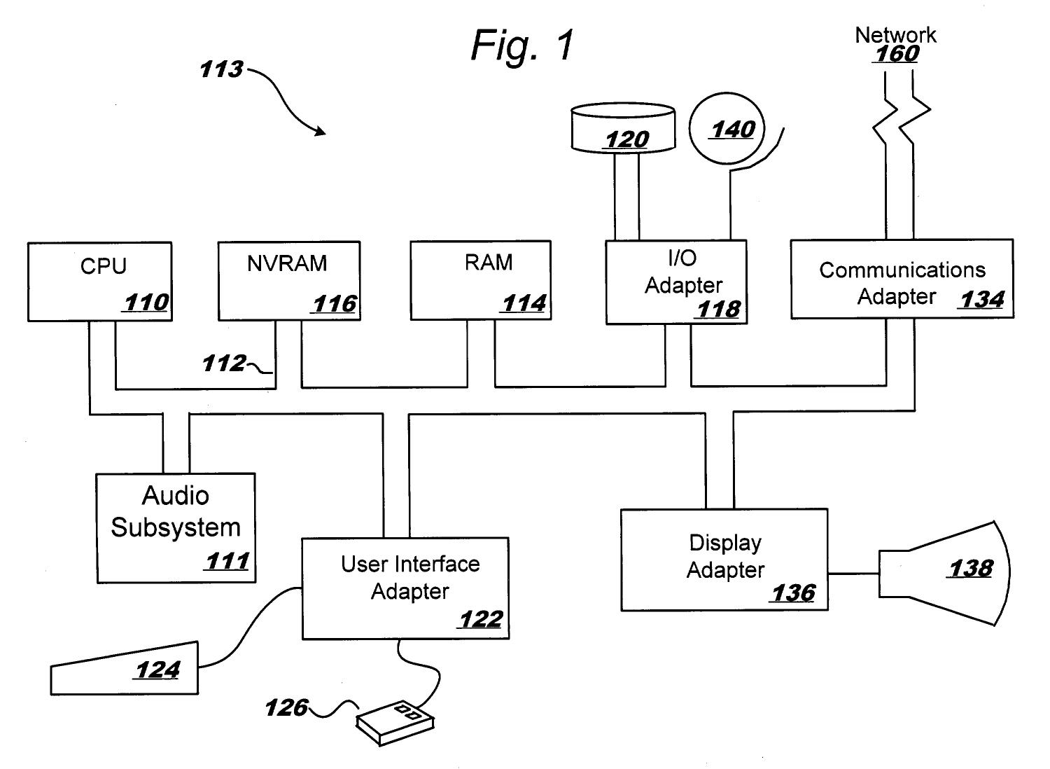

Referring now to the accompanying drawings, an particularly to FIG. 1, there is illustrated exemplary data processing system 113 configured in accordance with the present invention. The system 113 has a central processing unit (CPU) 110, which is coupled to various other components by system bus 112. A non-volatile memory (“NVRAM”) 116 is coupled to the system bus 112 and includes a basic input/output system (“BIOS”) that controls certain basic functions of the data processing system 113. Random access memory (“RAM”) 114, I/O adapter 118, and communications adapter 134 are also coupled to the system bus 112. I/O adapter 118 may be a small computer system interface (“SCSI”) adapter that communicates with a disk storage device 120. Communications adapter 134 interconnects bus 112 with an outside network 160 (e.g., the Internet) enabling the data processing system to communicate with other such systems. Input/Output devices are also connected to system bus 112 via user interface adapter 122 and display adapter 136. Keyboard 124 and mouse 126 are all interconnected to bus 112 via user interface adapter 122. Display monitor 138 is connected to system bus 112 by display adapter 136. In this manner, a user is capable of inputting to the system 113 throughout the keyboard 124 or mouse 126 and receiving output from the system via display 138. Audio subsystem 111 is coupled to system bus 112 and provides the necessary hardware to emit sound through one or more system speakers.

Implementations of the invention include implementations as a computer system programmed to execute the method or methods described herein, as a computer program product, and as a service in which a service provider installs code which performs the methods described herein. According to the computer system implementation, sets of instructions for executing the method or methods may be resident in the random access memory 114 of one or more computer systems configured generally as described above. Until required by the computer system, the set of instructions may be stored as a computer program product in another computer memory, for example, in disk drive 120 (which may include a removable memory such as an optical disk or floppy disk for eventual use in the disk drive 120). Further, the computer program product can also be stored at another computer and transmitted when desired to the user's workstation via network 160 or by an external network such as the Internet. One skilled in the art would appreciate that the physical storage of the sets of instructions physically changes the medium upon which it is stored so that the medium carries computer readable information. The change may be electrical, magnetic, chemical, biological, or some other physical change. While it is convenient to describe the invention in terms of instructions, symbols, characters, or the like, the reader should remember that all of these and similar terms should be associated with the appropriate physical elements.

According to a preferred embodiment of this invention, pre-characterized noise profiles are included for each of the devices to be shipped within the computer system. Preferably, each device is characterized during the manufacturing process. Although, alternatively, the characterization can be done on-site and post-installation as a part of a service provided by an on-site service provider.

When the characterization is done as a part of the manufacturing process, the self-generated audible noise emitted by each device to be profiled is isolated in an audio chamber, measured or recorded, and profiled according to the various embodiments described herein. In addition to profiling the device itself, the chassis the device is installed in may also be included in the profile. When profiled in-chassis, each device has associated with it several profiles according to the machine type the device is to be installed in. This is done because each device will have different noise levels and different noise characteristics emitted as a function of the chassis for each machine type produced.

The contents of the profile vary according to implementation. In its most straightforward embodiment, the profile contains industry standard wave file (wav) data produced by recording the sounds emitted from a representative device through a representative enclosure for a given machine type. Preferably, the wave data is chosen to be included in the profile when it can be shown through testing that, for most units shipped and when played back through the system speakers, the wave data has a beneficial effect from the perspective of a typical user. The beneficial effect can be one which operates to: smooth out an otherwise edgy sound; alter the pitch of the sound; remove pure tones from the sound; suppress the sound; and/or otherwise mask the sound. The profile can contain one or more instances of such wave data if it is found that, in production, a given device produces mutually exclusive acoustic noise characteristics as a function of the various production runs for the device. In this way, profiles can be updated as production for the device changes without rendering the profile obsolete relative to older devices. When multiple instances of wave data are provided in a single profile, application software can be adapted to allow users to select among the different instances of wave data per profile. This process can also be automated. It is foreseen that profiles containing only wave data will be particularly useful in manipulating transient sounds, such as the transient sounds made during data seek operations of hard disk 120.

In another implementation, rather than containing only wave data, the noise profiles can contain parameters describing the audible noise produced by the representative device in the representative chassis. For example, the profile can contain Fast Fourier Transform (FFT) parameters for synthesis by an FFT engine. The FFT engine can be implemented in software or in hardware. Details concerning FFT engines and other audio synthesis techniques are well known in the art and are omitted so as to not obfuscate the present disclosure in unnecessary detail. FFT parameters can be supplied in lieu of or in combination with wave data. When the type of sound being manipulated is more of a continuous tone, such as the audible noise produced by the rotational motion of direct access storage devices and fans, the FFT parameters characterize the harmonic components of the fundamental frequency more so than the fundamental itself. This is because, while no two devices have the same fundamental frequency in actual operation, the harmonics can be expected to be highly correlated between units and thus the harmonics are candidates for manipulation as described hereinbelow.

Note that while some embodiments are described in terms of FFT technology, it is understood that Applicants' invention is not to be limited thereto inasmuch as other audio synthesis techniques can be implemented by an artisan having ordinary skill in the audio art without departing from the teachings provided herein.

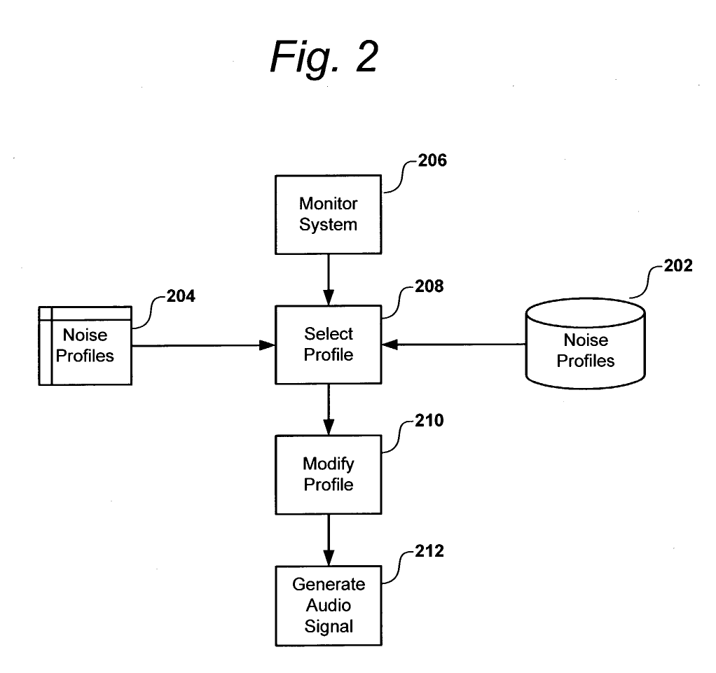

Referring to FIG. 2, there is illustrated a flow diagram presenting logic flow in accordance with an embodiment of the present invention wherein the noise profile or profiles as described above are stored in a storage device 202 readily accessible to the computer system. Storage device 202 can be the hard disk 120 or any other nonvolatile storage device such as a CD ROM or DVD device (not shown). In instances where fast access times are beneficial in retrieving the noise profiles, the profiles are also stored in a faster memory shown as item 204. This faster memory 204 can be RAM 114 or any other semiconductor-based memory with relatively fast access. In step 206, the state of the computer system and events in the computer system are monitored. System events and states which affect the audible characteristics of the machine, in particular, are monitored. For example, whether the machine is in a fully powered-on state or whether or it is in a standby or sleep state effects the audible emissions of the device, therefore, these states are monitored. Likewise, system events such as the accessing of hard disk drive 120 or a CD-ROM or DVD device are predictable and are also monitored. The predictability of hard disk drive accesses and the like is particularly notable because hard disk drive accesses are queued up and thus it is possible to predict beforehand and with a high degree of accuracy when the sounds will be generated in time. In this way is possible to predict the exact timing of upcoming events. Table 1 lists examples of events and states monitored in the computer system.

TABLE 1
Monitored States and Events

Power and Standby States
Hard Disk Drive Access
Hard Disk Drive Spin-up
CD-ROM Access
System Temperature
Video Card Temperature
Fan Tachometer
Chassis Type
Vendor Type (for each subsystem)

Table 2 is a partial list of the types of devices which emit audible noise and can be profiled according to the present embodiment of the invention.

TABLE 2
Sources of Audible Noise

CPU Cooling Fan (variable)
Chassis Cooling Fan (variable)
Power Supply Cooling Fan (variable)
Video Card Cooling Fan
Hard Disk Drive (access)
Hard Disk Drive (rotation)
Display (type determined by DDC data)
CD-ROM or DVD

Next, in step 208, the appropriate profile is selected from storage 202 or memory 204 according to the monitored system state or event as determined in step 206. If the selected profile is not in the memory 204, it is accessed from storage 202 and stored in memory 204 for more immediate access. If the selected profile resides in memory 204, no access to the storage 202 is necessary.

Note that the steps described herein can be performed by CPU 110 using code stored in RAM 114 (both of which are depicted in FIG. 1). Note that some or all of the steps described with respect to the illustrative embodiments can, alternatively, be performed by dedicated hardware as will be described hereinafter. It is preferable, however, that CPU 110 be utilized for the majority if not all of the steps described herein. Utilizing CPU 110 is preferable because there is no additional cost introduced into the system's design as a result.

In step 210, the selected profile is modified according to autonomic operations and/or user supplied input. Modification can be made to certain parameters within the profile which are known to or are likely to vary in practical installations. The modifications made in step 210 include but are not limited to: gain, phase, bandwidth, fundamental frequency, harmonic gain, and ratio of harmonic content to fundamental frequency. When modification to parameters is taken from user input, a query box can be displayed on display 138 along with sliders for the various parameters to be modified through user input via pointing device 126 and/or keyboard 124.

In step 212, an audio manipulation signal is generated taking into account the timing of events as predicted/determined/detected in step 206. Where the type of manipulation performed is timing/phase dependent, such as in a suppression type of manipulation, the timing of the audio manipulation signal can be made to line up with the predicted/determined/detected timing of step 206 or can be generated an offset therefrom according to a parameter stored in the profile or according to the phase modifications made in step 210. Where the type of manipulation performed is a masking operation, such as the production of a pleasant but otherwise unrelated sound, nearly exact timing information is expected to be of less importance.

In a first example of steps 206 thru 212 of FIG. 2 in operation, the assumptions are as follows: the source of noise is a hard disk drive; the type of noise is a hard disk drive access noise; the type of manipulation is to mask out the sound; the type of data contained in the profile is simple wave data (a prerecorded sound); the power state of the machine is a full power-on state; the hard disk drive manufacturer is IBM; and the hard disk drive type is 4834. Further, in this example it will be assumed that the delay time, measured from the time an access command is given at the CPU 110 to the time the actual sound is emitted, is 2 milliseconds. At step 206, it is determined that an access to the IBM 4834 disk 120 is queued and that the system is in full power-on mode. In step 208, the appropriate profile for the power status and the access event determined at step 206 is found in memory 204 and thus no access to storage 202 need take place. A different profile would be selected for the IBM 4834 disk if, for example, the system power state had been a suspended state or a sleep state. Processing then continues at step 210 where any user modifications or automatic profile modifications have been specified. Further assuming, for example, that the end-user entered a phase adjustment of ±500 microseconds, the profile is modified accordingly and processing continues at step 212. At step 212 the modified profile of step 210 is interpreted and per the parameters in the modified profile. Based on the type of manipulation specified in the profile, namely a masking modification by the use of wave data, a modification audio signal is generated. Specifically, the wave data is generated 2.5 milliseconds after the actual issuance of the access command to the IBM 4834 disk 120.

In step 212 of the first example, the generation of the masking signal can be suppressed if the noise profile is not stored in memory 204 and it is determined that it would take too much time to retrieve the proper noise profile from storage device 202. Alternatively, the fetching of the profile from the hard disk can be placed a higher priority than the original disk access request. Signal generation could be suppressed for this higher priority request, or a generic masking signal can be generated in place of an IBM 4834 disk specific signal.

In a second example, all of the assumptions made in the first example apply except in this second example, rather than wave data, the profile contains FFT parameters for synthesis by an FFT engine. In this example, the processing of steps 206, 208, and 210 remained the same. In step 212 it is determined that the profile data indicates FFT parameters and therefore that an FFT engine should be used to synthesize the masking sound. This determination can be inferred in step 212 by the data type, or the profile itself can specify the data type in a predetermined profile parameter.

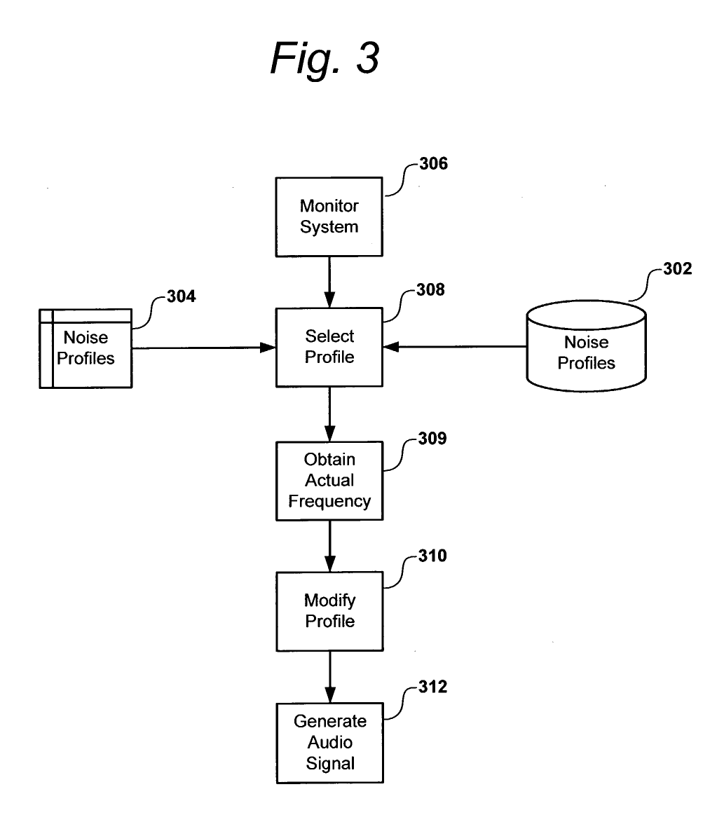

Referring to FIG. 3, there is illustrated a flow diagram presenting logic flow configured in accordance with an embodiment of the present invention where the fundamental frequency of the device under consideration is taken from other than the profile. In this embodiment it is recognized that the device in operation will not have the same fundamental frequency as the representative device used during the profile creation process. This embodiment is preferable where a beat frequency is undesirable such as in a modification which acts to suppress or alter the pitch of an emitted noise from a device. Except as described further herein, steps 306, 308, 310, and 312 are performed as described in steps 206, 208, 210, and 212 respectively in the embodiment of FIG. 2. The noise profiles stored in memory 304 and storage 302 are pre-characterized at the time of manufacture, or on-site as a part of a service provided by an on-site service provider, to include separate information for the fundamental frequency of the representative device and separate information for the harmonic components of the representative device. This can be accomplished in the most straightforward manner when specifying FFT parameters; however, the same information can be encoded into wave data and later decoded. The parameters describing harmonic components are taken as relative to the representative device's fundamental frequency, which is to be discarded. The representative device's fundamental frequency is taken as an assumed fundamental frequency for the actual operating device (until displaced). In step 309, the actual fundamental frequency of a device in operation is obtained. This actual fundamental frequency replaces the assumed fundamental frequency of the representative device as described by the profile. In step 310, the profile is modified to reflect the actual fundamental frequency detected/obtained. The parameters related to the harmonic components are modified at step 310 if it is desirable or required to do so. The use of the actual operating frequency will leave any modification waveform generated at step 312 with only a phase error. Additionally, the actual operating frequency can be repeatedly monitored and adjustments repeatedly made to hold the modification waveform to the actual operating frequency of a device. The remaining phase error can then be trimmed by a user through a user interface as described herein, supra, relative to the embodiment of FIG. 2. Isolation of the harmonic components from an assumed fundamental can be derived from wave data if wave data is all that is supplied within the profile. In this case, isolation of the harmonic components can be performed during step 310 through Fourier-type transforms. The derived harmonic components can then be combined with the obtained/actual fundamental frequency to produce a more useful profile. The modified profile can then be presented to the generation step 312 as either a wave data profile or an FFT profile irrespective of whether the profile originated as a wave data profile or as an FFT profile. Whether a profile is translated or not can be specified in the profile or can be undertaken independently on the part of the modification step. Finally, the audio generation step 312 interprets the profile and predicts the initial timing of the modification signal as described herein, supra, and generates the modification signal according to the profile. The audio modification signal is generated using the actual fundamental frequency detected/obtained in step 309 along with the harmonics specified in the profile—whether the harmonics were specified as FFT data or wave data. Without the user supplied gain, phase, and other parameters supplied in step 310, the modification signal is likely to have improper phase, gain, and/or other characteristics—particularly phase, since only the frequency aspect of the measured or estimated signal at step 309 can be relied upon as phase is dependent on speaker placement and user position. For an estimated frequency obtained at step 309—such as by estimating cooling fan speed/frequency when temperature is measured rather than measuring actual frequency—user-adjustable parameters entered in step 310 can include frequency adjustments.

In a third example, the operation of steps 306 thru 312 of FIG. 3 will now be given. The assumptions are as follows: the source of noise is a hard disk drive; the type of noise is hard-disk-drive-continuous-operation noise; the type of manipulation is to suppress the sound; the types of data contained in the profile are FFT parameters; the power state of the machine is a full power-on state; the hard disk drive manufacturer is IBM; and the hard disk drive type is 4834. At step 306, it is determined that the IBM 4834 disk 120 is spinning in full operation and that the system is in full power-on mode. In step 308, the appropriate profile for the power status and the hard disk status determined at step 306 is not found in memory 204 and thus access to storage 202 takes place and is thereafter stored in memory 204. In this example the event monitored at step 306, relative to the IBM 4834 disk 120, is the state change from not spinning to fully spun-up. This can also be an assumed event in the case that disk 120 is always fully spun-up; i.e., the event occurred at system power-on. The profile selected at step 308 contains FFT parameters describing the harmonic components relative to an assumed fundamental frequency (the fundamental frequency of the profiled representative device measured at the time the profiles were created). The profile also contains FFT parameters for the assumed fundamental frequency to potentially serve as an initial frequency. A different profile might be selected for the IBM 4834 disk if, for example, the system power state had been other than a fully powered-on state. Processing then continues at step 309 wherein the actual operating frequency of the IBM 4834 disk 120 is obtained. In this case, no tachometer is provided for disk 120 and therefore other means must be used to measure the frequency. The fundamental frequency of the disk in this example is obtained by repeatedly reading a given sector on the disk and measuring the average elapsed time between reads. This measured time will be related to rotational speed of the device which is in turn related to the fundamental frequency needed and can be calculated therefrom. It is deemed that one skilled in the art would know how to make such calculation and therefore such calculation is omitted so as to not obscure the present disclosure in unnecessary detail. It is notable that microphonic input or feedback is not required for any of the embodiments of this invention in performing any of the manipulations described herein. With the actual fundamental frequency of the device known, processing then continues at step 310 where any user modifications or automatic profile modifications have been specified. In this case, the assumed fundamental frequency FFT parameter specified in the profile is displaced by the appropriate FFT parameter specified according to the obtained frequency of step 309. Processing then continues at step 312. At step 312, the modified profile of step 310 is interpreted and per the parameters in the modified profile. Based on the type of manipulation specified in the profile, namely a suppressing modification by FFT synthesis, a modification audio signal is generated. Specifically, an FFT synthesized signal is generated according to the well-known synthesis techniques using the FFT parameter specified according to the obtained frequency of step 309 as the fundamental frequency and using the harmonic components FFT parameters specified in the original/stored profile. Adjustments can be made to the FFT parameters of the harmonic components as a function of the fundamental frequency used, as is well-known in the FFT synthesis art. The initial start of the generated audio signal of step 312 can be predicted to line up with the start time of the disk spin up event in much the same way as the access timing described relative to the first example.

In a fourth example which is a derivative of the third example, the profile data can be wave data. In this example, during profile modification step 310, the wave profile data can be converted into FFT parameters using Fourier analysis/transfers and the like. In which case, the converted parameters describing the assumed fundamental frequency are replaced by the actual frequency parameters based on the obtained frequency of step 309. These fundamental frequency parameters are then combined with the converted parameters describing the harmonic components of the wave data and passed to the audio signal generation step 312. Indeed, the audio signal generation step 312 may be implemented with a codec or a software driver that requires wave data as input. Therefore the synthesis at step 312 can include converting any converted FFT profile, which was itself converted from a wave data profile, back into wave data format has required.

In a fifth example, the assumptions of the third example described relative to FIG. 3 are adopted with the exception that the device is a fan device which has an integral tachometer. In this example the actual frequency obtained at step 309 is taken from the integral tachometer signal of the fan device. Depending on the type of tachometer, the tachometer signal may have to be divided by two or some other integer to arrive at the actual fundamental frequency of the fan. Improved suppression is expected when the phase error is trimmed out via user input during step 310.

In a sixth example, the assumptions of the third example described relative to FIG. 3 are also adopted. The exception here is that the device is a fan device which has no integral tachometer. Instead, the fan is designed to spin at a specific rotational rate relative to some predesigned temperature. In this example the actual frequency obtained at step 309 is estimated from the measured predesigned temperature. Improved suppression is expected when the frequency and phase error is trimmed out via user input during step 310.

User gain or amplitude adjustments are also expected to improve suppression or otherwise improve the performance of the manipulation. In addition, gain can be adjusted autonomically as a function of the volume level set at audio subsystem 111.

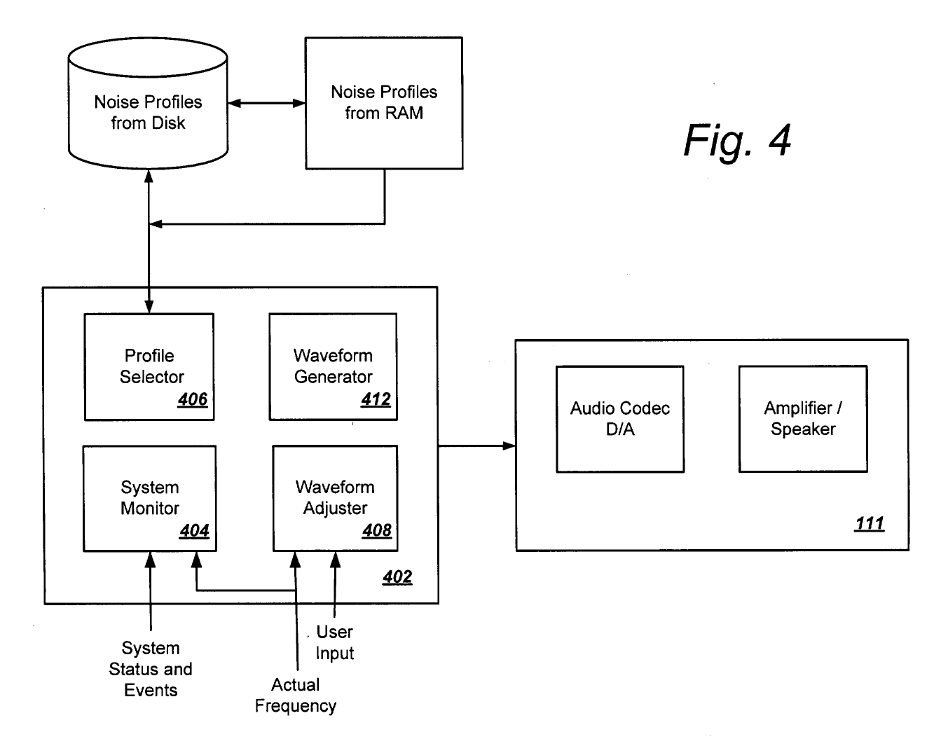

FIG. 4 illustrates a block diagram configured in accordance with an embodiment of the present invention where various of the logic performed in the embodiments described relatively to FIG. 2 and FIG. 3 are constructed in hardware. In construction, audio processor 402 can be implemented in its entirety as an application-specific IC (ASIC). Alternatively, audio processor 402 can be implemented entirely by the system CPU 110 by executing code stored in system RAM 114. Between these two extremes, a person of ordinary skill in the art would recognize other combinations to be possible. For example, system monitor 404 and profile selector 406 can be implemented by CPU 110, whereas waveform adjuster 408 and waveform generator 412 can be constructed as an ASIC performing FFT transform functions as well as the other functions performed and as described relatively to FIGS. 2 and 3. Generally speaking, system monitor 404 executes the logic flow described in steps 306 and 206 of FIGS. 3 and 2 respectively; likewise, profile selector 406 executes the logic flow described in steps 308 and 208; waveform adjuster 408 executes the logic flow described in steps 309 and 310 of FIG. 3, and the logic flow described in 210 of FIG. 2; in the same manner, waveform generator 412 executes the logic described in steps 312 and 212. Audio processor 402 sends its generated audio signal out to the audio subsystem 111.

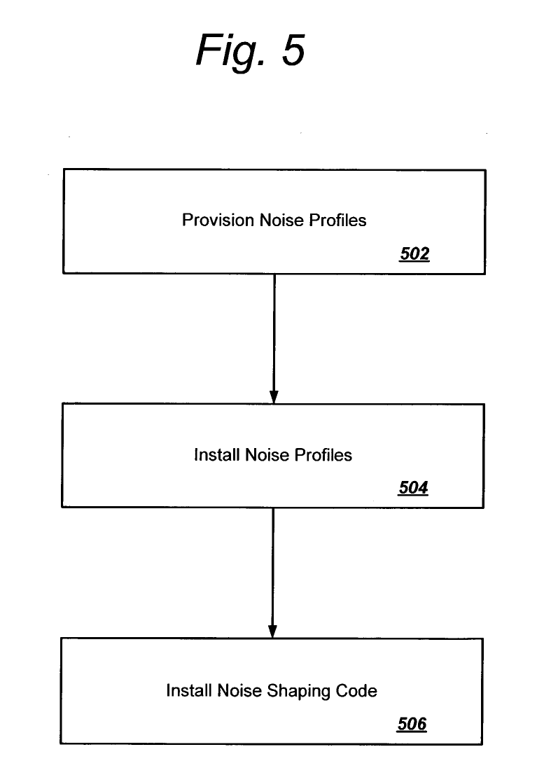

FIG. 5 illustrates the steps taken in deploying a service according an embodiment of the present invention wherein the provider of a service manages the noise emissions of one or more computers at a client's location. In step 502, the service provider provisions noise profiles based on the types of computers installed at the client's location. The noise profiles can be purchased from a third party who performs the actual pre-characterization as described herein, or alternatively, the service provider can generate the noise profiles. When the profiles are generated by the service provider, the generation of the noise profiles can be preperformed at the service provider's facility in much the same way as described relative to earlier embodiments wherein the manufacturer pre-characterizes the noise profiles. Alternatively, the generation of noise profiles can be performed at the clients' location which in some cases is expected to yield improved profiles, namely, when the client's location significantly differs acoustically when compared against the service provider's modeling facility. Noise profiles are provisioned by the service provider for each of the computers at the clients location based on the devices installed in each of the computers. Once the profiles have been provisioned, the service continues at step 504. At 504, the noise profiles are installed in each of the computers at the client's location which are to receive the service. At step 506, the service provider performs the task of installing the program code which manipulates/shapes the self-noise emitted by the devices within each of the installed computer systems. The installed program code contains instructions which execute the logic described herein relative to the embodiments of FIGS. 2 and 3.

The order of steps given herein is for exemplary purposes only and should not be interpreted as limiting with respect to other embodiments which are possible using a different order of steps in implementing the inventive concepts described herein.

In the drawings and specifications there has been set forth a preferred embodiment of the invention and, although specific terms are used, the description thus given uses terminology in a generic and descriptive sense only and not for purposes of limitation.

We claim as our invention:

1. A method comprising the steps of:
producing a noise profile for a device to be included with a computer system;
storing the noise profile in a storage accessible to the computer system;
monitoring events in the computer system and responding to selected events by selecting the noise profile; and
generating a noise shaping audio signal based upon the noise profile.

2. The method of claim 1 further comprising the steps of:
accepting user input for parameters related to the noise shaping audio signal; and
modifying the generated noise shaping signal according to the accepted input parameters.

3. The method of claim 2 wherein the input parameters are parameters selected from the group consisting of gain and phase parameters and wherein the selection of the noise profile in said monitoring step is dependent on system status.

4. A method comprising the steps of:
pre-characterizing the audible noise emitted by a device included with a computer system by producing a noise profile for the device, the noise profile including information related to the harmonic composition of a presumed fundamental frequency of the device;
storing the noise profile in a storage device accessible to the computer system;
monitoring system status and events in the computer system and responding to selected monitored status and events by selecting the noise profile;
obtaining an actual fundamental frequency for the device; and
generating a noise shaping audio signal as a function of the actual fundamental frequency and the harmonic compositional information stored in the noise profile.

5. The method of claim 4 further comprising the steps of:
accepting user input for parameters related to the noise shaping audio signal; and
modifying the generated noise shaping signal according to the accepted input parameters.

6. The method of claim 5 wherein the input parameters are parameters selected from the group consisting of gain, frequency, and phase parameters.

7. The method of claim 6 wherein said generating step includes the step of predicting, based upon a selected event, the timing of the audible noise emitted by the device and aligning the noise shaping audio signal according to the predicted timing.

8. The method of claim 4 wherein the device is a direct access storage device and wherein, in said obtaining step, the actual fundamental frequency of the direct access storage device is obtained by repeatedly reading a given sector on the direct access storage device and calculating the actual fundamental frequency based on the elapsed time between the repeated reads.

9. The method of claim 4 wherein, in said obtaining step, the actual fundamental frequency of the device is obtained from a tachometer associated with the device.

10. The method of claim 4 wherein the device is a fan and wherein, in said obtaining step, the actual fundamental frequency of the fan is estimated from temperature information associated with the fan.

11. Apparatus comprising:
a storage which stores a noise profile for an included device;
a system monitor which monitors system events;
a processor which is coupled to said storage and to said system monitor and which is effective to:
select the noise profile in response to selected monitored events as monitored by said system monitor; and
generate a noise shaping audio signal based upon the noise profile.

12. Apparatus of claim 11 wherein the processor is further effective to:
accept user input for parameters related to the noise shaping audio signal; and
modifying the generated noise shaping signal according to the accepted input parameters.

13. Apparatus of claim 12 wherein the input parameters are parameters selected from the group consisting of gain and phase parameters and wherein the selection of the noise profile is dependent on system status.

14. Apparatus comprising:
a storage device which stores a noise profile which characterizes the audible noise emitted by an included device, the noise profile including information related to the harmonic composition of a presumed fundamental frequency of the device;
a system monitor which monitors system status and events;
a processor which is coupled to said storage device and to said system monitor and which is effective to:
respond to selected monitored status and events by selecting the noise profile;
obtain an actual fundamental frequency for the device; and
generate a noise shaping audio signal as a function of the actual fundamental frequency and the harmonic compositional information stored in the noise profile.

15. Apparatus of claim 14 wherein the processor is further effective to:
accept user input for parameters related to the noise shaping audio signal; and
modify the generated noise shaping signal according to the accepted input parameters.

16. Apparatus of claim 15 wherein the input parameters are parameters selected from the group consisting of gain, frequency, and phase parameters.

17. Apparatus of claim 16 wherein the generation of the noise shaping audio signal includes (i) a prediction, based upon a predetermined selected event, of the timing of the audible noise emitted by the device and (ii) an alignment of the noise shaping audio signal according to the predicted timing.

18. Apparatus of claim 14 wherein the device is a direct access storage device and wherein the actual fundamental frequency of the direct access storage device is obtained by said processor repeatedly reading a given sector on the direct access storage device and calculating the actual fundamental frequency based on the elapsed time between the repeated reads.

19. Apparatus of claim 14 wherein the actual fundamental frequency of the device is obtained by said processor from a tachometer associated with the device.

20. Apparatus of claim 14 wherein the device is a fan and wherein the actual fundamental frequency of the fan is estimated by said processor from temperature information associated with the fan.

21. A product comprising:
a computer readable medium;
noise profile code stored on said medium accessibly to a computer system and effective to load a noise profile which contains information related to audio noise produced by a device comprised in the computer system; and
noise shaping code stored on said medium accessibly to a computer system and effective when executing in the computer system to monitor system status and events in the computer system, to respond to selected monitored status and events by selecting the noise profile, and to respond to selection of the noise profile by generating a noise shaping audio signal based upon the noise profile.

22. A product comprising:
a computer readable medium;
noise profile code stored on said medium accessibly to a computer system and effective to load a noise profile which contains pre-characterized information related to audio noise produced by a device comprised in the computer system including the harmonic composition of a presumed fundamental frequency of the device; and
noise shaping code stored on said medium accessibly to a computer system and effective when executing in the computer system to monitor system status and events in the computer system, to respond to selected monitored status and events by selecting the noise profile, to obtain an actual fundamental frequency for the device, and to respond to selection of the noise profile by generating a noise shaping audio signal based upon the actual fundamental frequency and the harmonic compositional information stored in the noise profile.
